(19) United States
(12) Patent Application Publication
(10) Pub. No.: US 2014/0337693 A1
(43) Pub. Date: Nov. 13, 2014

(54) LOW-COMPLEXITY DECODER FOR CONVOLUTIONAL CODING

(71) Applicant: SAGEM DEFENSE SECURITE, Boulogne-Billancourt (FR)

(72) Inventors: Alain Chiodini, Boulogne-Billancourt (FR); Michel Gillet, Boulogne-Billancourt (FR)

(73) Assignee: SAGEM DEFENSE SECURITE, Boulogne-Billancourt (FR)

(21) Appl. No.: 14/361,295

(22) PCT Filed: Nov. 28, 2012
(86) PCT No.: PCT/EP2012/073853

§ 371 Date: May 28, 2014

(30) Foreign Application Priority Data
Nov. 29, 2011 (FR) 1160925

(51) Int. Cl. H03M 13/23

(52) U.S. Cl. CPC H03M 13/235
USPC 714/786

(57) ABSTRACT

The invention relates, according to the first form thereof, to a transmission error correction method, wherein at least two encoded binary series from a binary series that is to be transmitted and encoded by means of a convolutional code are received from a communication channel. Said method is characterized in that same comprises the following steps: producing, from two received encoded binary series, comparison binary series that coincide in the absence of transmission errors on the communication channel; comparing the comparison binary series and forming a detection binary series corresponding to the logic operation OU-exclusive of the two comparison binary series; and, in the event that the comparison binary series diverge from a divergence point, verifying if the series made up of P bits of the detection binary series from the divergence point corresponds to a listed transmission error and correcting, if necessary, the received encoded binary series.

### FIELD OF THE INVENTION

The field of the invention is that of error detecting and correcting codes, and more precisely that of so-called convolutional codes. Within this scope, the invention relates to a low-complexity decoder for convolutional codes.

### BACKGROUND OF THE INVENTION

Convolutional codes form a flexible and efficacious class of error detecting and correcting codes. These are the codes currently most widely used in fixed and mobile communications systems. The term “convolutional” means that the series of coded bits is the result of the convolution of the series of bits of information by the coefficients of at least two fixed binary sequences called generator polynomials.

Encoding binary data to be emitted is done by means a convolutional encoder: the output of this device depends on the current information to be encoded (instant n) as well as of the preceding information (instants n-1, n-2, n-K+1) and of the state of the encoder. The parameter K is called the constraint length of the code and defines the number of states of the convolutional code (2^{K-1}). In practice, a convolutional encoder is made by means of a shift register and “eXclusives OR (XOR)”.

The classic way of decoding a code is to compare the received sequence y(n) to all possible sequences x(n) likely to be emitted and select the most plausible of them. This way of proceeding has an exponential complexity (increasing with the size of the received sequence) and consequently cannot be done in practice. The reduction in distance between the observed message and the decoded message is done according to the criterion of maximum resemblance. The most widespread decoding method currently, and especially integrated into a good number of mass products (GSM, WiFi, etc.), is based on the Viterbi algorithm (this is a dynamic programming algorithm which considers the repetitive structure of the trellis generated from generator polynomials of the convolutional code used). It allows upon receipt of a word y to determine the closest codeword x (according to the criterion of maximum likelihood). Decoding with maximum likelihood consists of searching in the trellis of the code for path closest to the received sequence.

A disadvantage of the Viterbi decoder is that its complexity is high and it cannot be compatible with the software resources of the receiver for executing decoding. This complexity also means electric power consumption which can prove excessive vis-à-vis the resources of some receivers (portable units, in particular).

There is therefore a need for a decoding solution of convolutional codes having a very low complexity relative to those based on the Viterbi algorithm.

It should also be noted that in practice the Viterbi decoder cannot execute decoding of convolutional codes having a constraint length greater than 7, since its complexity would. grow to the point of becoming prohibitive. It is understood therefore that the correction power (or coding gain) is in reality limited.

### EXPLANATION OF THE INVENTION

The aim of the invention is to propose a low-complexity convolutional code decoder and propose for this purpose according to a first aspect a method for correction of transmission errors wherein at least two encoded binary series each correspond to the result of the convolution of the same binary series to be transmitted with the coefficients of a respective generator polynomial and are received from a communications channel, characterised in that it comprises the steps consisting of:
producing, from two received encoded binary series, comparison binary series which coincide in the absence of transmission errors over the communications channel;
comparing the comparison binary series and form a detection binary series corresponding to the logic operation XOR of the two comparison binary series;
in case of divergence of comparison binary series from a divergence point, verify if the sequence constituted by P bits of the detection binary series from the divergence point corresponds to a listed transmission error and if needed correct the received encoded binary series.

According to a second aspect the invention relates to a data receiver, characterised in that it comprises a convolutional code decoder comprising a memory for storing listed transmission errors and a processor configured to execute the method according to the first aspect of the invention.

The invention also extends to a data-transmission system comprising a transmitter and a receiver according to the second aspect of the invention.

### BRIEF DESCRIPTION OF THE DIAGRAMS

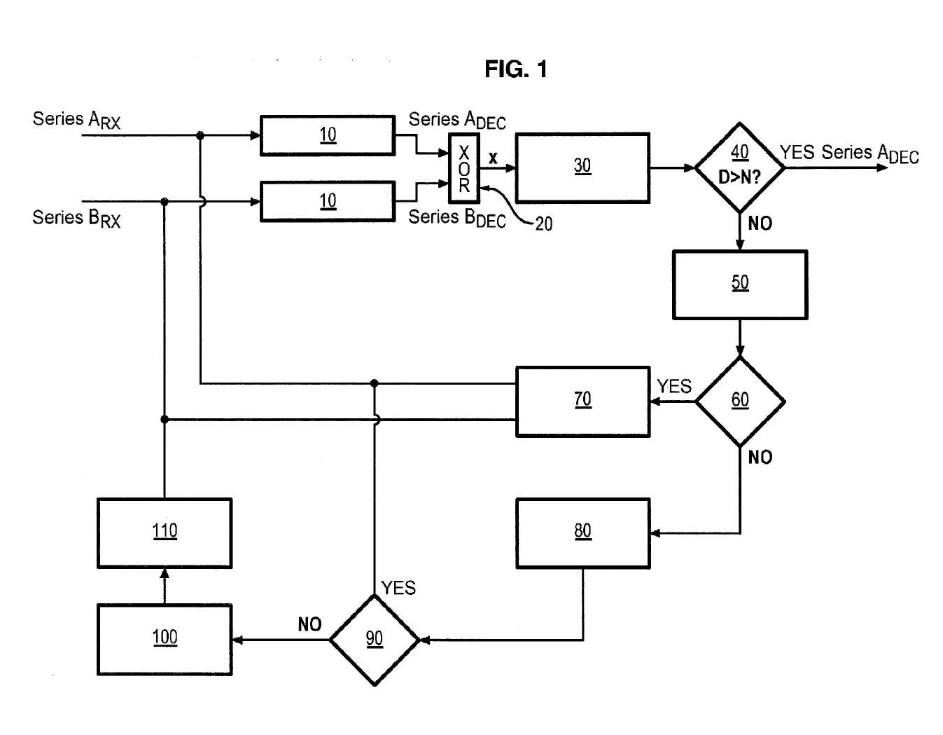

Other aspects, aims and advantages of the present invention will emerge more clearly from the following detailed description of preferred embodiments thereof, given by way of non-limiting example, and made in reference to the sole attached FIG. 1 which illustrates an outline schematic of the decoder forming the subject of the invention.

### DETAILED DESCRIPTION OF THE INVENTION

According to its initial aspect the invention relates to a method for correction of transmission errors in at least two encoded binary series resulting from encoding of a message to be transmitted by a convolutional code and transmitted over a communications channel.

Each of the encoded binary series preferably results of the convolutional encoding of the same binary “source” series to be transmitted executing two generator polynomials. This results in two encoded binary series, each of which corresponds to the result of the convolution of a binary “source” series to be transmitted with the coefficients of a respective generator polynomial, specifically a first binary series resulting from the convolution of the binary series to be transmitted with a first generator polynomial and a second binary series resulting from the binary series to be transmitted with a second generator polynomial different of the first generator polynomial.

By way of purely illustrative example, the encoded binary series are produced by a encoder implementing the convolutional code running the generator polynomials [133]₈ and [171]₈ (octal notation) over a constraint length equal to 7. The coefficients of these polynomials are the following: [1011011]₂ and [1111001]₂.

It is evident that the invention is not limited by the number of generator polynomials exploited by the convolutional code being used. So, if the convolutional code used comprises more than two generator polynomials and, consequently, produces more than two binary series, this can lead to the simplest case based on the use of two binary series (case preferably described hereinbelow) by processing for example, in parallel or successively, all the couples of binary series which can be formed with the set of binary series produced by the convolutional code used.

In reference to FIG. 1, the method for correction of errors starts with receiving from the communications channel at least two received encoded binary series A_{RX} and B_{RX} (these two series are extracted from the same “source” binary series by deinterlacing).

During a first step represented by the block 10 in FIG. 1, comparison binary series A_{DEC}, B_{DEC}, which coincide in the absence of transmission errors over the communications channel, are produced from the two received encoded binary series A_{RX}, B_{RX}.

According to a first embodiment, the comparison binary series A_{DEC}, B_{DEC} are produced by creating the convolution of each of the received encoded binary series A_{RX}, B_{RX}, with the coefficients of the generator polynomial having served to encode the other received encoded binary series. Hereinbelow M is noted as the binary series to be transmitted, P_{A}, respectively P_{B}, the generator polynomial corresponding to producing the encoded series A_{TX} (=M*P_{A}), respectively B_{TX} (=M*P_{B}), transmitted over the transmission channel from which it is received in the form of the received encoded series A_{RX}, respectively B_{RX}. Within the scope of this first embodiment, the polynomial P_{B} is used for convolution of the series A_{RX} and the polynomial P_{A} for convolution of the series B_{RX}. In the absence of transmission errors over the channel (A_{TX}=A_{RX} and B_{TX}=B_{RX}) the comparison binary series are identical: A_{DEC}=A_{RX}*P_{B}=A_{TX}*P_{B}=M*P_{A}*P_{B} and B_{DEC}=B_{RX}*P_{A}=B_{TX}*P_{A}=M*P_{B}*P_{A}.

According to a second embodiment, the comparison binary series A_{DEC}, B_{DEC} is produced by making the deconvolution of each of the received encoded binary series by means of the generator polynomial having served to encode them on emission. In the absence of transmission errors over the channel, the comparison binary series are identical and correspond to the series to be sent: A_{DEC}=A_{RX}*1/P_{A}=A_{TX}*1/P_{A}=M*P_{A}*1/P_{A}=M and B_{DEC}=B_{RX}*1/P_{B}=B_{TX}*1/P_{B}=M*P_{B}*1/P_{B}=M.

It is evident from here on that in an advantageous variant embodiment of the invention these two embodiments are used jointly to produce two pairs of comparison binary series.

As shown by the block 20, the comparison binary series A_{DEC}, B_{DEC} are next compared and a detection binary series X corresponding to the logic operation XOR of the two comparison binary series is formed.

In the absence of errors, the comparison binary series A_{DEC} and B_{DEC} must coincide perfectly. In the presence of errors, they will diverge from a certain point (divergence point D) easily identifiable due to the detection binary series X. The time index associated with this point precisely marks the start of the sequence of errors. The block 30 in FIG. 1 shows the detection of such a divergence point, while the block 40 illustrates that if D exceeds the length N of the binary sequence to be decoded, no correction is made and the decoding ends.

As shown by the blocks 50 and 60, the next step is to verify if the sequence constituted by P bits of the detection binary series from the point of divergence corresponds to a listed transmission error. The received encoded binary series are corrected, if needed (block 70).

It will be noted that P is for example equal to 2K-1 in the case of the first embodiment, and for example equal to K in the case of the first embodiment, K representing the constraint lengths of the convolutional code.

According to an embodiment, said sequence is utilised to calculate (block 50) a metric corresponding for example to the whole number comprising the consecutive bits X(D) to X(D+P-1). This metric identifies if needed the sequence of errors detected (block 60 during which it is verified whether the metric is known). So, within the scope of the invention, a certain number of trivial errors (single, double, triple and quadruple) has been listed, each associated with a value of the metric. Therefore, if the metric calculated in this way from the sequence constituted by the consecutive bits X(D) to X(D+P-1) corresponds to a listed error, the received encoded binary series are corrected (block 70).

The values of the metric retained for detection of trivial errors can be the following (the list below is not exhaustive):

| | Sequences of detected single, double, | | | | | | | | |
|---|---|---|---|---|---|---|---|---|---|
| Met- | triple and quadruple trivial errors | | | | | | | | |
| ric | Index | D − 4 | D − 3 | D − 2 | D − 1 | D | D + 1 | D + 2 | D + 3 |
| 112 | Series A_{RX} | | | | | X | | | |
| | Series B_{RX} | | | | | | | | |
| 87 | Series A_{RX} | | | | | X | | | |
| | Series B_{RX} | | | | | | X | | |
| 99 | Series A_{RX} | | | | | X | | | |
| | Series B_{RX} | | | | | | | X | |
| 121 | Series A_{RX} | | | | | X | | | |
| | Series B_{RX} | | | | | | | | X |
| 78 | Series A_{RX} | | | | | | | | |
| | Series B_{RX} | | | | | X | | | |
| 118 | Series A_{RX} | | | | | | X | | |
| | Series B_{RX} | | | | | X | | | |
| 82 | Series A_{RX} | | | | | | | X | |
| | Series B_{RX} | | | | | X | | | |
| 64 | Series A_{RX} | | | | | | | | X |
| | Series B_{RX} | | | | | X | | | |
| 72 | Series A_{RX} | | | | | X | X | | |
| | Series B_{RX} | | | | | | | | |
| 105 | Series A_{RX} | | | | | | | | |
| | Series B_{RX} | | | | | X | X | | |
| 108 | Series A_{RX} | | | | | X | | X | |
| | Series B_{RX} | | | | | | | | |
| 93 | Series A_{RX} | | | | | | | | |
| | Series B_{RX} | | | | | X | | X | |
| 126 | Series A_{RX} | | | | | X | | | X |
| | Series B_{RX} | | | | | | | | |
| 71 | Series A_{RX} | | | | | | | | |
| | Series B_{RX} | | | | | X | | | X |
| 125 | Series A_{RX} | | | | X | | | | |
| | Series B_{RX} | | | | X | | | | |
| 111 | Series A_{RX} | | | | | X | X | | |
| | Series B_{RX} | | | | | | X | | |
| 81 | Series A_{RX} | | | | | | X | | |
| | Series B_{RX} | | | | | X | X | | |
| 103 | Series A_{RX} | | | X | | | | | |
| | Series B_{RX} | | | X | X | | | | |
| 67 | Series A_{RX} | | | | X | X | | | |
| | Series B_{RX} | | | | X | X | | | |
| 84 | Series A_{RX} | | | X | X | | | | |
| | Series B_{RX} | | | X | | X | | | |
| 94 | Series A_{RX} | X | | X | | | | | |
| | Series B_{RX} | X | X | | | | | | |
| 98 | Series A_{RX} | | | | X | | X | | |
| | Series B_{RX} | | | | X | | X | | |

If in block 60 of FIG. 1 the metric does not correspond to any of the listed errors, according to an embodiment of the invention Viterbi decoding of the received encoded binary series can be performed.

Preferably, the invention proposes the mechanism as per when in block 60 of FIG. 1 the metric does not correspond to any of the listed errors. First of all, the hypothesis is made that only one of the received encoded binary series (for example A_{RX}) is corrupted and a correction is made (block 80), which is supposed to be an error, for example a single error, in this received encoded binary series to form a corrected series (noted as A′_{RX} hereinbelow).

The aim next is to validate this correction. For this, a new comparison binary series A′_{DEC} which coincides in the absence of transmission errors over the communications channel with the comparison binary series B_{DEC} formed from the second received encoded binary series is formed from the corrected series A′_{RX}. The new comparison binary series A′_{DEC} is obtained similarly to the binary series A_{DEC}, according to one of the two embodiments described previously.

The correction made to the series A_{RX} is validated (block 90) if the divergence between the new comparison binary series A′_{DEC} and the comparison binary series B_{DEC} formed from the second received encoded binary series appears later than the divergence previously detected between the two comparison binary series A_{DEC} and B_{DEC}. So if the time index linked to the new divergence point exceeds the preceding divergence point by at least one unit then the correction is validated, and the error-correction method continues.

If not, the correction on A_{RX} is cancelled (block 100), and it is supposed that the series B_{RX} is corrupted. A correction is made (block 110) which is supposed to be an error on this series B_{RX} and the error-correction method continues.

Preferably, the error-correction method ends when the number of corrected errors exceeds a given limit.

Two embodiments of the comparison binary series A_{DEC} and B_{DEC} were described previously. In an advantageous variant embodiment of the invention, these two embodiments are used jointly to produce two pairs of comparison binary series. Next, two binary detection series are formed, each from the comparison of the comparison binary series of one of the pairs and two metrics are calculated, m1 (corresponding to executing the first embodiment) and m2 (corresponding to executing the second embodiment) in the presence of transmission errors. Since a metric can correspond to several profiles of transmission errors, having two metrics can discriminate a single transmission error profile by clearing up with a second metric the ambiguity resulting from a first metric. A larger number of errors can be corrected in this way.

It is understood therefore that the invention relates to the use of one or the other metric only, and preferably to the use of both metrics together, the metric m2 acting to clear up any ambiguity highlighted by the metric m1 or vice-versa.

The performances of the decoder forming the subject matter of the invention are close to those of the Viterbi decoder in the case of the use of hard decisions at the demodulator output on the receiver side. However, the complexity of the decoder according to the invention is very low compared to that of the Viterbi decoder such that such a decoder can be implemented despite limited software resources. The decoder according to the invention therefore represents an advantageous alternative to the Viterbi decoder, significantly reducing the surface of silicon, the number of operations and the electric power consumption necessary for implementation and operation of a decoder of convolutional codes. This alternative also proves advantageous in that it enables decoding of convolutional codes having a constraint length greater than 7 (which the Viterbi decoder cannot do in practice due to its complexity which would be prohibitive) and therefore enables making substantial coding gains.

An application which could be made for the invention relates to communications performing audio compression according to the codec G.726 for example, especially within the scope of communications based on the wireless telephony standard DECT (Digital European Cordless Telephone). The bit rate of the codec G.726 can be 16, 24, 32 or 40 kbits/s. The invention proposes configuring the codec at a bit rate lower than the maximal rate (for example at 16 kbits/s in applications where it is normally used at 32 kbits/s) and utilising the now free binary space (16 kbits/s) to run channel coding.

It should be apparent that the invention is not limited to the correction method of transmission errors according to its first aspect, but also extends to receiving data incorporating a convolutional code decoder comprising a memory for storing listed transmission errors and a processor configured to execute the method according to the first aspect of the invention. The invention also extends to a data-transmission system comprising a transmitter and a receiver incorporating a convolutional code decoder in line with the invention. The transmitter can especially incorporate a coder configured to run compression of voice data according to a codec at a bit rate lower than the maximal bit rate of said codec and to execute convolutional coding of voice data compressed exploiting the binary space freed up by the use of said low bit rate.

1. A method for correction of transmission errors wherein at least two encoded binary series each correspond to the result of the convolution of the same binary series to be transmitted with the coefficients of a respective generator polynomial and are received from a communications channel, wherein said method comprises the steps of:
producing, from two received encoded binary series, comparison binary series which coincide in the absence of transmission errors over the communications channel;
comparing the comparison binary series and forming a detection binary series corresponding to the logic operation eXclusive OR (XOR) of the two comparison binary series;
in case of divergence of the comparison binary series from a divergence point, verifying if the sequence constituted by P bits of the detection binary series from the divergence point corresponds to a listed transmission error and if needed correcting the received encoded binary series.

2. The method according to claim 1, wherein to produce the comparison binary series, the convolution of each of the received encoded binary series is carried out with the coefficients of the generator polynomial having served to encode the other received encoded binary series.

3. The method according to claim 1, wherein to produce the comparison binary series, the deconvolution of each of the received encoded binary series is carried out by means of the generator polynomial having served to encode said encoded binary series.

4. The method according to claim 1, wherein no correction is made if the divergence point corresponds to a position exceeding the length of the binary sequence to be decoded.

5. The method according to claim 1, wherein if the sequence constituted by P bits of the detection series from the divergence point does not correspond to a listed transmission error, further comprising the steps of:
correcting an error in a first of the received encoded binary series to form a corrected series;
forming from the corrected series a new comparison binary series which in the absence of transmission errors over the communications channel coincides with the comparison binary series formed from the second received encoded binary series;
validating the correction made to the first of the received encoded binary series if the divergence between the new comparison binary series and the comparison binary series formed from the second received encoded binary series appears later than the divergence previously detected between the two comparison binary series formed from the first and the second received encoded binary series.

6. The method according to claim 5, wherein if the correction made to the first of the received encoded binary series is not validated, an error in the second of the received encoded binary series is corrected.

7. The method according to claim 1, wherein the method ends when the number of corrected errors exceeds a given limit.

8. The method according to claim 1, wherein a first detection binary series is formed from a first comparison binary series and a second detection binary series is formed from a second, comparison binary series, and wherein if several listed errors are identified by means of the first or second detection binary series, discrimination is made among these listed errors by verifying whether one and/or the other of these errors has also been identified by means of the other detection binary series,
wherein the first comparison binary series is produced by the convolution of each of the received encoded binary series carried out with the coefficients of the generator polynomial having served to encode the other received encoded binary series, and
wherein the second comparison binary series is produced by the deconvolution of each of the received encoded binary series carried out by means of the generator polynomial having served to encode said encoded binary series.

9. A data receiver, characterised in that it comprises a convolutional code decoder comprising a memory for storing listed transmission errors and a processor configured to conduct the method according to claim 1.

10. A data transmission system comprising a transmitter and a receiver according to claim 9.

11. The data transmission system according to claim 10, wherein the transmitter comprises a coder configured to execute voice data compression according to a codec at a bit rate lower than the maximal bit rate of said codec and to execute convolutional coding of now compressed voice data exploiting the binary space freed by the use of said low bit rate.

12. The method according to claim 2, wherein the method ends when the number of corrected errors exceeds a given limit.

13. The method according to claim 3, wherein the method ends when the number of corrected errors exceeds a given limit.

14. The method according to claim 4, wherein the method ends when the number of corrected errors exceeds a given limit.

15. The method according to claim 5, wherein the method ends when the number of corrected errors exceeds a given limit.

16. The method according to claim 6, wherein the method ends when the number of corrected errors exceeds a given limit.
